(19) United States
(12) Patent Application Publication
(10) Pub. No.: US 2013/0126975 A1
(43) Pub. Date: May 23, 2013

(54) THIN FILM TRANSISTOR ARRAY AND CIRCUIT STRUCTURE THEREOF

(71) Applicants: Chao-Yun Cheng, Taoyuan County (TW); Shin-Jien Kuo, New Taipei City (TW); Chih-Chiang Chuang, New Taipei City (TW)

(72) Inventors: Chao-Yun Cheng, Taoyuan County (TW); Shin-Jien Kuo, New Taipei City (TW); Chih-Chiang Chuang, New Taipei City (TW)

(73) Assignee: AU OPTRONICS CORPORATION, Hsinchu (TW)

(21) Appl. No.: 13/401,816

(22) Filed: Feb. 21, 2012

(30) Foreign Application Priority Data
Nov. 21, 2011 (TW) 100142529

(51) Int. Cl. H01L 29/786

(52) U.S. Cl. 257/368; 257/E29.273

(57) ABSTRACT

A thin film transistor array and a circuit structure thereof are provided. The circuit structure includes a patterned metal layer, a transparent conductive layer and a dielectric layer. The transparent conductive layer is formed on and contacts a top surface of the patterned metal layer. The dielectric layer overlies and contacts the patterned metal layer and the transparent conductive layer. In addition, the dielectric layer has a contact window to expose a portion of the transparent conductive layer. The transparent conductive layer on the top surface of the patterned metal layer can protect the surface layer metal against damage during fabrication of the contact window.

### CROSS-REFERENCE TO RELATED APPLICATION

This application claims the priority benefit of Taiwan application serial no. 100142529, filed Nov. 21, 2011. The entirety of the above-mentioned patent application is hereby incorporated by reference herein and made a part of this specification.

### BACKGROUND OF THE INVENTION

1. Field of the Invention

The present invention relates to a semiconductor component array and a circuit structure thereof, and more particularly, to a thin film transistor array and a circuit structure thereof.

2. Description of Related Art

With the rapid development of electronic technology, thin film transistor liquid crystal displays (TFT LCD) have gradually become the main stream in the market in recent years due to its advantages of high definition, high room utilization rate, low power consumption and zero radiation.

In fabrication of a TFT array, a contact window is required to be formed to conduct circuits and pads of different layers. However, when the contact window is formed by plasma etching, a surface layer metal (e.g. a Molybdenum layer) of the metal circuits or pads can be damaged at the same time, such that a lower layer metal (e.g. an Aluminium layer) may be corroded or formed with hillocks in subsequent processes, thus decreasing the yield.

### SUMMARY OF THE INVENTION

Accordingly, the present invention provides a circuit structure of a thin film transistor (TFT) array, which includes a transparent conductive layer formed on the surface layer metal of a patterned metal layer to avoid variation in uniformity of the surface layer metal during the physical vapor deposition (PVD) and plasma etching processes.

The present invention provides a circuit structure of a TFT array, which includes a patterned metal layer, a transparent conductive layer, and a dielectric layer. The transparent conductive layer is formed on and contacts a top surface of the patterned metal layer. The dielectric layer overlies and contacts the patterned metal layer and the transparent conductive layer. In addition, the dielectric layer has a contact window to expose a portion of the transparent conductive layer.

In one embodiment, the patterned metal layer includes a gate metal layer or a source/drain metal layer.

The present invention additionally provides a TFT array, which includes a gate metal layer, a channel layer and a source/drain metal layer. The gate metal layer, channel layer and source/drain metal layer are adapted to form a plurality of TFTs. The TFT array further includes a pixel electrode layer having a plurality of pixel electrodes coupled to the TFTs, respectively. The TFT array further includes a transparent conductive layer and a dielectric layer. The transparent conductive layer is affixed to a top surface of the gate metal layer or the source/drain metal layer. The dielectric layer overlies the transparent conductive layer and the corresponding gate metal layer or the source/drain metal layer. The dielectric layer has a contact window to expose a portion of the transparent conductive layer.

In one embodiment, the transparent conductive layer and the corresponding gate metal layer or the source/drain metal layer have the same pattern.

In one embodiment, the patterned metal layer is a metal layer stack. A surface metal layer of the metal layer stack contacts the transparent conductive layer, and the material of the surface metal layer comprises Molybdenum (Mo), Molybdenum Nitride (MoN), Molybdenum Tungsten (MoW), or Titanium (Ti).

In one embodiment, the material of the transparent conductive layer includes Indium Tin Oxide (ITO), Indium Zinc Oxide (IZO), or Indium Gallium Zinc Oxide (IGZO).

In view of the foregoing, in the present invention, a transparent conductive layer is formed over the patterned metal layer to protect the surface layer metal of the patterned metal layer in fabricating the contact window later. In particular, taking fabrication of the contact window by plasma etching as an example, when the plasma etching rate of the transparent conductive layer is less than the plasma etching rate of the surface layer metal of the patterned metal layer, the transparent conductive layer can better provide an effect similar to the etching stop which effectively protect the surface layer metal of the patterned metal layer against plasma etching. As such, the present invention can effectively prevent the surface layer metal of the patterned metal layer from being damaged and hence avoid the corrosion and hillocks during fabrication of the contact window, which facilitates improving the yield. In addition, it is no longer necessary to form an over-thick surface layer metal to protect the lower layer metal, thus reducing the thickness of the surface layer metal and hence the fabrication cost.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 illustrates fabrication of a contact window in a circuit structure of a TFT array according to one embodiment of the present invention.

FIG. 2 illustrates a circuit diagram of a TFT array and a driver IC according to one embodiment of the present invention.

FIG. 3 is a cross-sectional view of the TFT array of FIG. 2, taken along line A-A′ thereof.

FIG. 4 illustrates a variation to the embodiment of the TFT array of FIG. 2.

### DESCRIPTION OF THE EMBODIMENTS

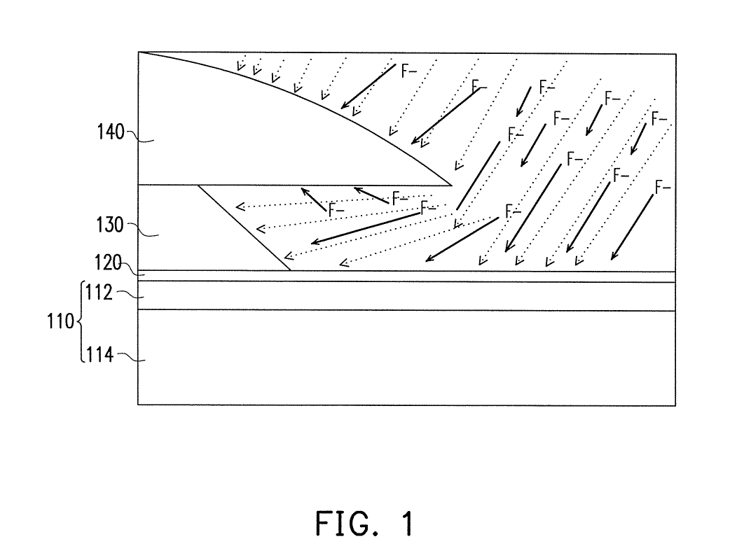

FIG. 1 illustrates fabrication of a contact window in a circuit structure of a thin film transistor (TFT) array according to one embodiment of the present invention. As shown in FIG. 1, a metal layer stack 110 is, for example, a gate metal layer, source or drain metal layer, which includes a surface metal layer 112 and a lower metal layer 114. The material of the surface metal layer 112 is, for example, molybdenum (Mo), and the material of the lower surface layer 114 is, for example, Aluminium. A transparent conductive layer 120 is disposed on the metal layer stack 110. The material of the transparent conductive layer 120 is, for example, Indium Tin Oxide (ITO). A protective layer 130 and an insulation layer 140 are sequentially disposed on the transparent conductive layer 120. The material of the protective layer 130 is, for example, Silicon Nitride (SiNx). During fabrication of a contact window W1 for conducting circuits of a driver IC and the gate metal layer using, for example, plasma etching, the surface metal layer 112 tends to be damaged by fluoric-based plasma thus resulting in corrosion or surface hillocks. Therefore, the present invention achieves an effect similar to etching stop by using characteristics of the material of the transparent conductive layer 120 that has an approximately zero etching rate in fluoric-based plasma, thereby effectively protect the surface metal layer 112 against damage caused by plasma etching. However, the present invention is not intended to be limited to this particular embodiment described herein. Rather, the present invention could be equally applied to any surface electrode that needs to be protected during fabrication of a semiconductor component array, such as, during fabrication of a contact window W2 of a dielectric layer of a TFT array.

In practice, the contact window W2 may be a contact window used to conduct circuits or pads of different layers of the TFT array, such as, the contact window W2 of the dielectric layer between a pixel electrode and a drain electrode of the TFT array, or the contact window W1 between the driver IC and the gate metal layer, which are described below in detail.

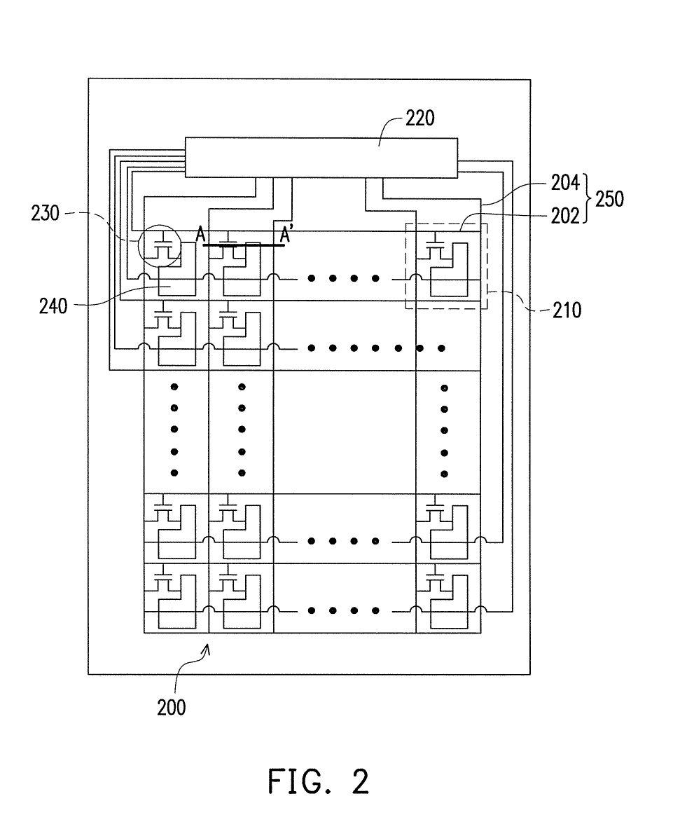

FIG. 2 illustrates a circuit diagram of a TFT array and a driver IC according to one embodiment of the present invention. The TFT array 200 consists of scan lines 202, signal lines 204, pixel units 210 and a driver IC 220. Each pixel unit includes one TFT 230, one pixel electrode 240, one scan line 202 and one signal line 204. The driver IC 220 is disposed at a peripheral area of the TFT array 200 and is connected to a lead line 250 via a contact window so as to control each pixel unit 210 through corresponding scan line 202 and signal line 204.

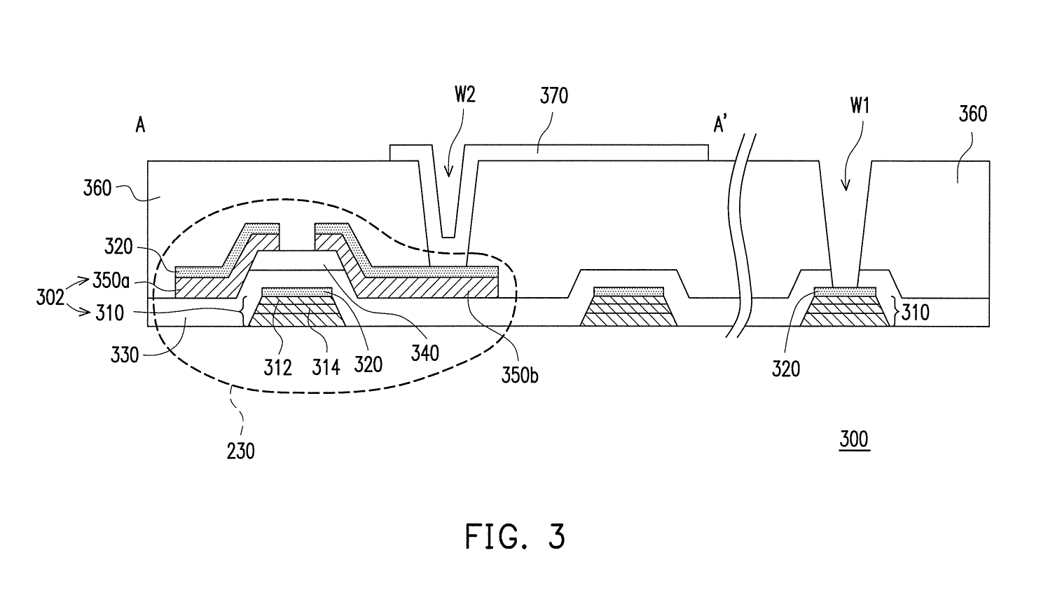

FIG. 3 is a cross-sectional view of the TFT array 200 of FIG. 2, taken along line A-A′ thereof. Referring to FIG. 3, the circuit structure 300 of the TFT array of the present embodiment includes a patterned metal layer 302, a transparent conductive layer 320 and a dielectric layer 360. The patterned metal layer 302 refers to a gate metal layer 310 or a source 350a/drain 350b metal layer. The TFT 230 includes the gate metal layer 310, a gate insulation layer 330, a channel layer 340, the source 350a/drain 350b metal layer, a pixel electrode layer 370, the transparent conductive layer 320, and the dielectric layer 360. Each of the gate metal layer 310 and source 350a/drain 350b metal layer is a metal layer stack, and the material of a surface layer metal of the metal layer stack is, for example, Molybdenum (Mo), Molybdenum Nitride (MoN), Molybdenum Tungsten (MoW), or Titanium (Ti). The material of the transparent conductive layer 320 includes Indium Tin Oxide (ITO), Indium Zinc Oxide (IZO), or Indium Gallium Zinc Oxide (IGZO).

The transparent conductive layer 320 is affixed over the surface metal layer of the gate metal layer 310 or the source 350a/drain 350b metal layer. The dielectric layer 360 overlies the transparent conductive layer 320 and the corresponding gate metal layer 310 or source 350a/drain 350b metal layer. The dielectric layer 360 has a contact window W1, and the contact window W1 exposes a portion of the transparent conductive layer 320. The pixel electrode layer 370 is coupled to the drain 350b of the TFT 230 through the contact window W1. In addition, as shown in FIG. 3, the transparent conductive layer 320 may be disposed over the entire surface metal layer of the patterned metal layer 302. The transparent conductive layer 320 and the corresponding gate metal layer 310 or source 350a/drain 350b metal layer may have the same pattern and, therefore, no additional photo mask is required during fabrication. In addition, the gate metal layer 310 may serve as a photo mask, such that the pattern of the transparent conductive layer 320 can be achieved by back-mask exposure.

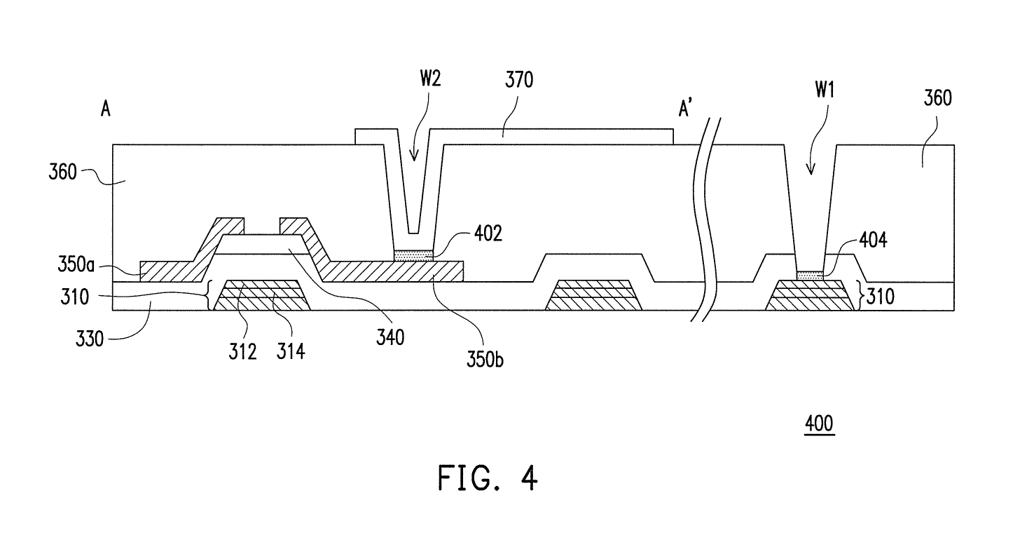

FIG. 4 illustrates a different circuit structure 400 of the TFT array 200 of FIG. 2. As shown in FIG. 4, a first transparent conductive layer 402 and a second transparent conductive layer 404 are respectively provided on specific areas of the source 350a/drain 350b metal layer and the gate metal layer 310 where the contact windows W1 and W2 are desired rather than other areas covered by the dielectric layer 360. In other words, the transparent conductive layer (including the first transparent conductive layer 402 and the second transparent conductive layer 404) has a pattern different from that of the gate metal layer 310 or the source 350a/drain 350b metal layer. By which, similar effect of etching stop can be achieved by the first transparent conductive layer 402 and the second transparent conductive layer 404 for effectively protects the gate metal layer 310 and the source 350a/drain 350b metal layer from being damaged during fabrication of the contact windows W1 and W2.

In summary, in the circuit structure of the TFT array of the present invention, a transparent conductive layer is formed on the patterned metal layer to protect the surface metal layer of the patterned metal layer. In addition, in fabrication of the contact window, the etching rate of the material of the transparent conductive layer is far lower than the etching rate of the material of the surface metal layer. Therefore, in fabrication of the contact window using, for example, physical vapor deposition (PVD) and plasma etching, the present invention can achieve an effect similar to etching stop so as to avoid damage to the surface metal layer of the patterned metal layer, and avoid corrosion and surface hillock of the lower metal layer in a subsequent high temperature process due to the damage of the surface metal layer, thereby improving uniformity of the surface metal layer. In other words, it is no longer necessary to form an over-thick surface metal layer and, therefore, the thickness of the surface metal layer can be reduced. Besides, the transparent conductive layer can protect the metal circuits against scratch so as to provide a comprehensive protection to the patterned metal layer. Moreover, the fabrication of the transparent conductive layer can be integrated into the conventional fabrication process, which can eliminate the additional photo mask and fabrication process modification thus effectively reducing the fabrication cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit structure of a thin film transistor array, comprising:
a patterned metal layer;
a transparent conductive layer formed on and contacting a top surface of the patterned metal layer; and
a dielectric layer overlying and contacting the patterned metal layer and the transparent conductive layer, wherein the dielectric layer has a contact window to expose a portion of the transparent conductive layer.

2. The circuit structure of the thin film transparent array according to claim 1, wherein the transparent conductive layer and the patterned metal layer have the same pattern.

3. The circuit structure of the thin film transparent array according to claim 1, wherein the patterned metal layer comprises a gate metal layer or a source/drain metal layer.

4. The circuit structure of the thin film transparent array according to claim 1, wherein the patterned metal layer is a metal layer stack, a surface metal layer of the metal layer stack contacts the transparent conductive layer, and the material of the surface metal layer comprises Molybdenum, Molybdenum Nitride, Molybdenum Tungsten, or Titanium.

5. The circuit structure of the thin film transparent array according to claim 1, wherein the material of the transparent conductive layer comprises Indium Tin Oxide, Indium Zinc Oxide, or Indium Gallium Zinc Oxide.

6. A thin film transistor array comprising:
a gate metal layer, a channel layer and a source/drain metal layer adapted to form a plurality of thin film transistors;
a pixel electrode layer comprising a plurality of pixel electrodes, the pixel electrodes coupled to the thin film transistors, respectively;
a transparent conductive layer affixed to a top surface of the gate metal layer or the source/drain metal layer; and
a dielectric layer overlying the transparent conductive layer and the corresponding gate metal layer or the source/drain metal layer, wherein the dielectric layer has a contact window to expose a portion of the transparent conductive layer.

7. The thin film transistor array according to claim 6, wherein the transparent conductive layer and the corresponding gate metal layer or the source/drain metal layer have the same pattern.

8. The thin film transistor array according to claim 6, wherein the patterned metal layer is a metal layer stack, a surface metal layer of the metal layer stack contacts the transparent conductive layer, and the material of the surface metal layer comprises Molybdenum, Molybdenum Nitride, Molybdenum Tungsten, or Titanium.

9. The thin film transistor array according to claim 6, wherein the material of the transparent conductive layer comprises Indium Tin Oxide, Indium Zinc Oxide, or Indium Gallium Zinc Oxide.
